(19) United States
(12) Patent Application Publication
(10) Pub. No.: US 2015/0255216 A1
(43) Pub. Date: Sep. 10, 2015

(54) CAPACITOR WITH LOW EQUIVALENT SERIES INDUCTANCE

(71) Applicant: QUALCOMM Incorporated, San Diego, CA (US)

(72) Inventors: Lalan Jee Mishra, San Diego, CA (US); Shree Krishna Pandey, San Diego, CA (US); Irfan Khan, San Diego, CA (US); Nazanin Darbanian, San Diego, CA (US); John David Eaton, San Diego, CA (US)

(73) Assignee: QUALCOMM INCORPORATED, San Diego, CA (US)

(21) Appl. No.: 14/201,469

(22) Filed: Mar. 7, 2014

(51) Int. Cl. H01G 4/30; H05K 1/18; H01L 49/02

(52) U.S. Cl. CPC H01G 4/30; H01L 28/40; H05K 1/18; H05K 1/185

(57) ABSTRACT

A capacitor with low equivalent series inductance includes multiple electrode layers arranged in parallel with alternating ones of the electrode layers connected together to form the two electrodes of the capacitor. A first set of the electrode layers are connected by an outer wall. A second set of the electrode layers are connected by a central post. Terminals on the capacitor can be spaced on a surface so that signals can be conveniently routed when the capacitor is mounted on or in a printed circuit board or integrated circuit package. Terminals can be included on opposing surfaces of the capacitors to provide for stacking. Additionally, one of the terminals substantially surrounds the other terminal and can provide electromagnetic shielding.

### BACKGROUND

1. Field

The present invention relates to capacitors and, more particularly, to multi-layer capacitors with low equivalent series inductance.

2. Background

As the speed and performance of integrated circuits has continued to increase, components, such as capacitors, used with the integrated circuits also need to operate at increasingly high frequencies. Real capacitors include parasitic inductance and resistance in addition to the desired capacitance. The parasitic inductance and resistance may be referred to and modeled as equivalent series inductance (ESL) and equivalent series resistance (ESR), respectively.

As the operating frequencies of electronic devices increase, the importance of these parasitic effects also increases. A high-performance processor, for example, can demand high currents (e.g., tens of amps) and the current can change rapidly (e.g., nanoseconds). When a capacitor used in a power distribution network for a high-performance processor has high ESL, the voltage supplied to the processor can exhibit large voltage drops that impair performance of the processor. Additionally, the power distribution network can have resonances that cause excessive voltage drops that result in operational failures.

Some prior systems have used voltage regulators with faster response times and capacitors closer to the load (e.g., on an integrated-circuit package). These approaches are insufficient. Providing capacitors that have low ESL allows higher performance systems to be produced.

### SUMMARY

Capacitors with low equivalent series inductance (ESL) are provided. In an aspect, the capacitors include multiple electrode layers arranged in parallel with alternating ones of the electrode layers connected together to form the two electrodes of the capacitor. A first set of the electrode layers are connected by an outer wall. A second set of the electrode layers are connected by a central post. Each electrode layer in the first set has an opening that separates it from the central post. Each electrode layer in the second set has a smaller outer dimension than the electrode layers in the first set so that the electrode layers in the second set are separated from the outer wall.

Terminals on the capacitors can be spaced on a surface so that signals can be conveniently routed when the capacitors are mounted on or in a printed circuit board or integrated circuit package. Terminals can be included on opposing surfaces of the capacitors to provide for stacking. Additionally, one of the electrodes substantially surrounds the other electrode and can provide electromagnetic shielding. The capacitors may be used, for example, in power distribution networks with the shielding used on a voltage supply.

In one aspect, a capacitor is provided that includes a plurality of first electrode layers including two of the plurality of first electrode layers disposed on outer surfaces of the capacitor; a wall connecting outer edges of the plurality of first electrode layers; a plurality of second electrode layers, the plurality of first electrode layers and the plurality of second electrode layers interleaved in alternating planes and separated by a dielectric; and a post connecting inner edges of the plurality of second electrode layers, the post passing through the plurality of first electrode layers.

In one aspect, a capacitor is provided that includes a plurality of first electrode layers including two of the plurality of first electrode layers disposed on outer surfaces of the capacitor; a means for connecting outer edges of the plurality of first electrode layers; a plurality of second electrode layers, the plurality of first electrode layers and the plurality of second electrode layers interleaved in alternating planes and separated by a dielectric; and a means for connecting inner edges of the plurality of second electrode layers.

Other features and advantages of the present invention should be apparent from the following description which illustrates, by way of example, aspects of the invention.

### BRIEF DESCRIPTION OF THE DRAWINGS

The details of the present invention, both as to its structure and operation, may be gleaned in part by study of the accompanying drawings, in which like reference numerals refer to like parts, and in which:

FIG. 1 is a cutaway isometric view of a capacitor according to a presently disclosed embodiment;

FIG. 2 a top view of the capacitor of FIG. 1;

FIG. 3 is a cross-sectional view along line 3-3 of FIG. 2;

FIG. 4 is a bottom view of another capacitor according to a presently disclosed embodiment;

FIG. 5 is a bottom view of another capacitor according to a presently disclosed embodiment;

FIG. 6 is a cutaway isometric view of another capacitor according to a presently disclosed embodiment;

FIG. 7 is an isometric view of an installed capacitor according to a presently disclosed embodiment;

FIG. 8 is an isometric view of another installed capacitor according to a presently disclosed embodiment;

FIG. 9 is an isometric view of another installed capacitor according to a presently disclosed embodiment;

FIG. 10 is an exploded view of another installed capacitor according to a presently disclosed embodiment; and

FIG. 11 is an isometric view of an integrated circuit package with a capacitor according to a presently disclosed embodiment.

### DETAILED DESCRIPTION

The detailed description set forth below, in connection with the accompanying drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in simplified form in order to avoid obscuring such concepts.

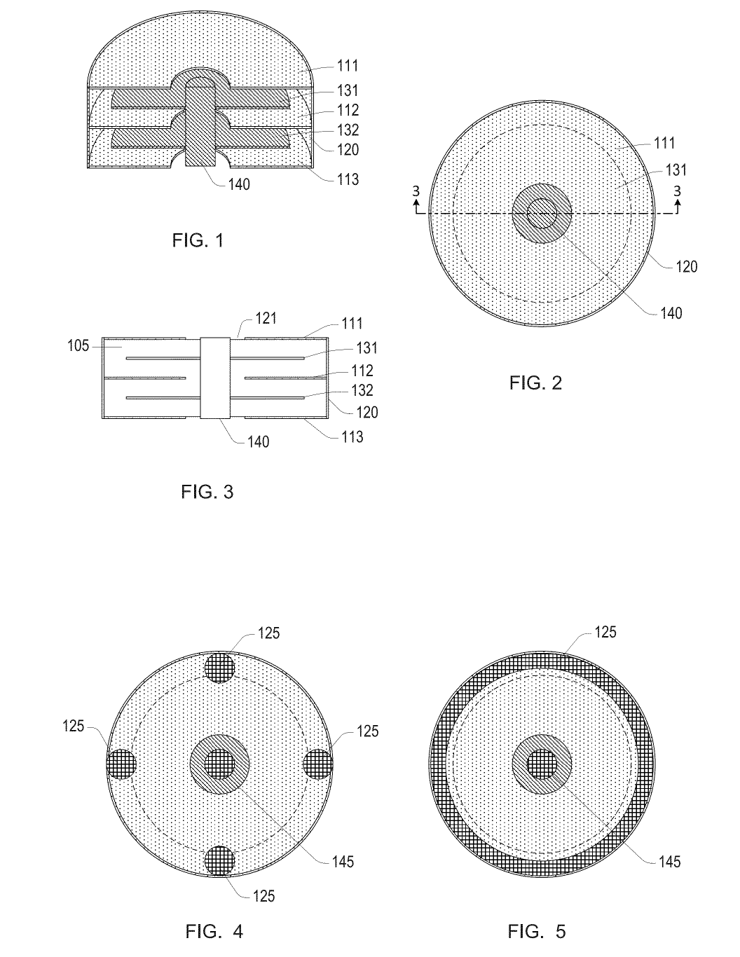

FIG. 1 is a cutaway isometric view of a capacitor according to a presently disclosed embodiment. FIG. 2 is a top view and FIG. 3 is a cross-sectional view of the capacitor of FIG. 1. The capacitor can have low ESL. Thus, it can be used effectively with high-frequency devices.

The capacitor includes first electrode layers 111, 112, 113 and second electrode layers 131, 132. In the embodiment of FIG. 1, the electrode layers are discs. The electrode layers are generally formed of metal, for example, silver or nickel. Two of the first electrode layers (111, 113) are located on outer surfaces of the capacitor.

A wall 120 surrounds the capacitor and electrically connects the first electrode layers 111, 112, 113 at their outer edges. The wall 120 is generally formed of metal, for example, tin. The first electrode layers 111, 112, 113 have an outer diameter that is greater than the outer diameter of the second electrode layers 131, 132. This provides separation between the second electrode layers 131, 132 and the wall 120 so that the second electrode layers 131, 132 are insulated from the wall 120.

A post 140 extends through the centers of the electrode layers. In the embodiment shown in FIG. 1, the post 140 is cylindrical and solid. Alternatively, the post 140 may be hollow. The second electrode layers 131, 132 have central openings that correspond to the size of the post 140 so that the post 140 electrically connects the second electrode layers 131, 132 at their inner edges. The post is generally formed of metal, for example, tin. The first electrode layers 111, 112, 113 have openings 121 in their centers. The openings 121 have a diameter larger than that of the post 140 so that the first electrode layers 111, 112, 113 are separated from and insulated from the post 140.

The spaces between the first electrode layers 111, 112, 113 and the second electrode layers 131, 132 are filled with a dielectric 105, for example, ceramic.

The first electrode layers 111, 112, 113 may be referred to collectively as a cathode and the second electrode layers 131, 132 may be referred to collectively as an anode. However, the illustrated capacitor is not polarized. The cathode includes the first electrode layer 111 on the top surface of the capacitor, the first electrode layer 113 on the bottom surface of the capacitor, and the wall 120. The cathode thus forms substantially the complete external surface of the capacitor. The cathode can provide electromagnetic shielding of the anode. For example, the capacitor may be used for power supply filtering with the cathode connected to a ground reference and the anode connected to a voltage supply. Noise on the anode of the capacitor (e.g., from high-frequency changes in current from the voltage supply) is shielded by the cathode, which is connected to the ground reference.

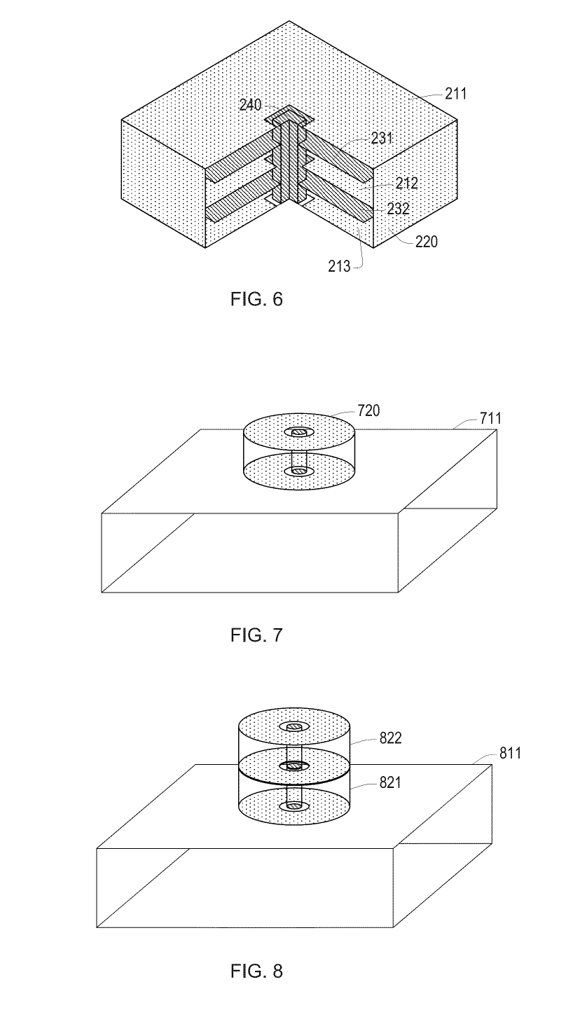

FIG. 6 is a cutaway isometric view of another capacitor according to a presently disclosed embodiment. The capacitor of FIG. 6 also has low ESL. The capacitor of FIG. 6 is similar to the capacitor of FIG. 1. However, the capacitor of FIG. 6 has electrode layers that are rectangular or square plates. The other components of the capacitor have corresponding shapes.

The capacitor of FIG. 6 includes first electrode layers 211, 212, 213. A wall 220 surrounds the capacitor and electrically connects the first electrode layers 211, 212, 213. The capacitor includes second electrode layers 231, 232. A post 240 extends through the electrode layers and electrically connects the second electrode layers 231, 232. In the embodiment illustrated in FIG. 6, the post 240 has a square cross-section.

The first electrode layers 211, 212, 213 have an outer dimension that is greater than the outer dimension of the second electrode layers 231, 232. This provides separation between the second electrode layers 231, 232 and the wall 220 so that the second electrode layers 231, 232 are insulated from the wall 220. The second electrode layers 231, 232 have openings that correspond to the size of the post 240 so that the post 240 contacts the second electrode layers 231, 232. The first electrode layers 211, 212, 213 have openings that are larger than the post 240 so that the first electrode layers 211, 212, 213 are separated from and insulated from the post 240.

FIG. 4 is a bottom view of another capacitor according to a presently disclosed embodiment. FIG. 4 shows an arrangement of a terminal on the capacitor. The capacitor of FIG. 4 may be of various forms; however, to provide a specific example, the capacitor of FIG. 4 will be described with reference to the capacitor of FIG. 1.

An anode terminal 145 is located on the bottom of the post 140. The shape of the anode terminal 145 may correspond to the shape of the bottom of the post 140. For example, in an embodiment where the post 145 is hollow, the anode terminal 145 may have an annular shape. Four cathode terminals 125 are spaced about the periphery of the bottom electrode layer 113. Other numbers of terminals may also be used. The cathode terminals 125 may alternatively or additionally be connected to the wall 120. The anode terminal 145 and the cathode terminals 125 may be, for example, solder balls. The cathode terminals 125, in an embodiment, are located on the surface of the capacitor and do not extend through or into the capacitor. Thus, plate area of the first electrode layers 111, 112, 113 and second electrode layers 131, 132 is not used for the terminals.

The gaps between the cathode terminals 125 may be used, for example, when the capacitor is mounted on a printed circuit board to route signals in the area between the capacitor and the printed circuit board. For example, a signal may be routed to connect to the anode terminal 145 in one of the gaps between the cathode terminals 125.

Similar terminals may be located on the top of the capacitor. Terminals on the top of the capacitor may be used to mount the capacitor without concern for its orientation. Terminals on the top of the capacitor may be used to connect multiple capacitors in a stack. A similar arrangement of terminals may be used on capacitors of other shapes. In an embodiment, the anode terminals on the top and bottom of the capacitor are connected via the post and the cathode terminals on the top and bottom of the capacitor are connected via the wall.

FIG. 5 is a bottom view of another capacitor according to a presently disclosed embodiment. The capacitor is similar to the capacitor of FIG. 4. However, the capacitor of FIG. 5 has cathode terminal 125 distributed about the periphery of the bottom electrode layer 113. The cathode terminal 125 may alternatively or additionally be connected to the wall 120. An anode terminal 145 is located on the bottom of the post 140. Similar terminals may be located on the top of the capacitor. A similar arrangement of terminals may be used on capacitors of other shapes.

The disclosed capacitors may be fabricated by processes similar to those used for conventional multilayer ceramic capacitors.

Uses of the disclosed capacitors include uses with printed circuit boards and integrated circuit packages. Some of the ways the capacitors can be used are illustrated in FIGS. 7-9. The capacitors illustrated in FIGS. 7-9 may be, for example, any of the capacitors of FIGS. 1-6. FIGS. 7-9 are described for printed circuit boards.

FIG. 7 illustrates a capacitor 720 mounted on a surface 711 of a printed circuit board. The capacitor 720 may be attached, for example, by solder reflow.

FIG. 8 illustrates a stacked configuration with a second capacitor 822 mounted on a first capacitor 821 that is mounted on a surface 811 of a printed circuit board. The first capacitor 821 includes terminals on both its top and bottom surfaces. The capacitors may be attached, for example, by solder reflow.

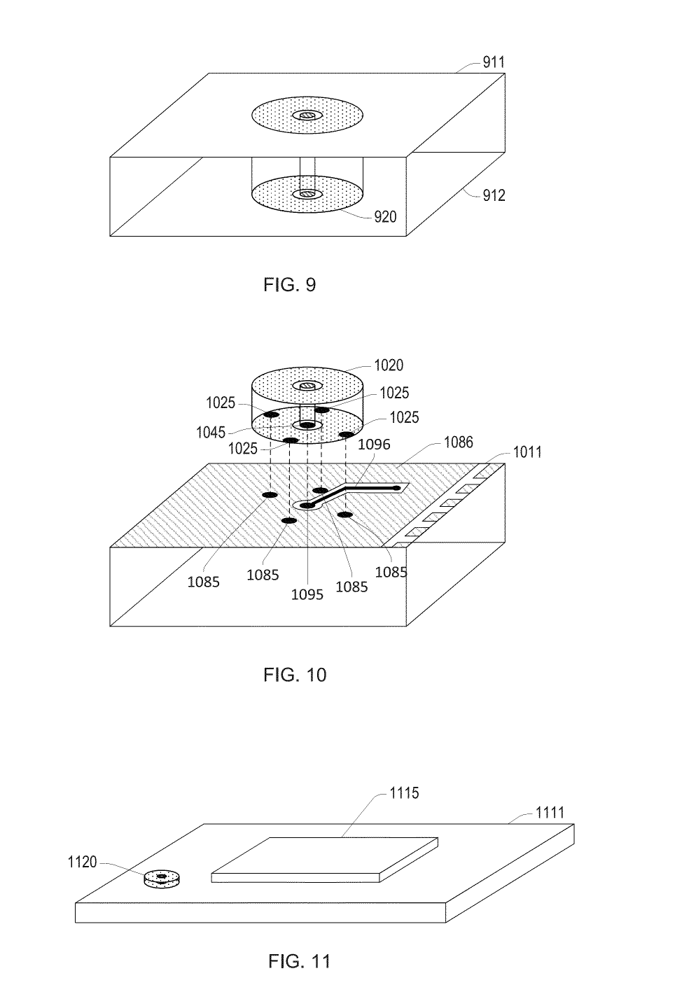

FIG. 9 illustrates an embedded configuration with a capacitor 920 disposed between a first surface 911 of a printed circuit board and a second surface 912 of the printed circuit board. Cylindrical capacitors are particularly suited for an embedded configuration as they can fit in circular holes created by drilling operations used in fabricating the printed circuit board. A capacitor may also be embedded in a printed circuit board between internal layers. Additionally, multiple, stacked capacitors may be embedded in a printed circuit board.

FIG. 10 is an exploded view of a capacitor 1020 on a surface 1011 of a printed circuit board. The capacitor 1020 includes cathode terminals 1025 distributed near the perimeter of its bottom surface and an anode terminal 1045 at the center of the bottom surface. The capacitor 1020 may be, for example, the capacitor of FIG. 4. The cathode terminals 1025 connect to corresponding connection points 1085 on the printed circuit board. In the example embodiment, the connection points 1085 are connected to a ground plane 1086 on the surface 1011 of the printed circuit board.

A signal trace 1096 is also located on the surface 1011 of the present board. The signal trace 1096 and the ground plane 1086 may be, for example, etched from a copper sheet. The signal trace 1096 is located in an area where the ground plane 1086 is vacant. The signal trace 1096, which may route a power supply used on the print circuit board, connects to a connection point 1095. The connection point 1095 connects to the anode terminal 1045 of the capacitor 1020. The signal trace 1096 routes in spaces between the connection points 1085 (which correspond to cathode terminals 1025).

FIG. 11 is an isometric view of an integrated circuit package 1111. The integrated circuit package 1111 includes an integrated circuit die 1115 and a capacitor 1120. The capacitor 1120 may, for example, provide power supply filtering for the integrated circuit die 1115. The capacitors described herein may be used in other manners with integrated circuit packages, for example as illustrated for printed circuit boards in FIGS. 7-10.

The disclosed capacitors have an ESL that is much lower, for example, one fourth, than that of conventional multilayer ceramic capacitors. The locations of the capacitor terminals allow the capacitor to be connected to a circuit with low loop inductance.

For ease of illustration, the capacitors are illustrated with five electrode layers; however, a capacitor may have hundreds of layers. Similarly, the capacitors are not illustrated to scale.

Although particular embodiments of the invention are described above, many variations of the invention are possible. For example, the outer wall may not be continuous. For another example, the inner post may not be located in the center of the electrode layers. Additionally, different shapes may be used including different shapes for the various components of a single capacitor. Additionally, features of the various embodiments may be combined in combinations that differ from those described above. For example, a capacitor that has square electrode layers may have a cylindrical post.

Directional terms, such above, above, below, left, and right, are used to describe some features. This terminology is used to provide clear and concise descriptions. The terms are relative and no particular absolute orientation should be inferred.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent presently preferred embodiments of the invention and are therefore representative of the subject matter which is broadly contemplated by the present invention. It is further understood that the scope of the present invention fully encompasses other embodiments that may become obvious to those skilled in the art and that the scope of the present invention is accordingly limited by nothing other than the appended claims.

What is claimed is:

1. A capacitor, comprising:
a plurality of first electrode layers including two of the plurality of first electrode layers disposed on outer surfaces of the capacitor;
a wall connecting outer edges of the plurality of first electrode layers;
a plurality of second electrode layers, the plurality of first electrode layers and the plurality of second electrode layers interleaved in alternating planes and separated by a dielectric; and
a post connecting inner edges of the plurality of second electrode layers, the post passing through the plurality of first electrode layers.

2. The capacitor of claim 1, wherein the wall completely surrounds the plurality of first electrode layers.

3. The capacitor of claim 1, wherein the post is solid.

4. The capacitor of claim 1, wherein the post is cylindrical.

5. The capacitor of claim 1, wherein the plurality of first electrode layers and the plurality of second electrode layers are discs.

6. The capacitor of claim 1, wherein the plurality of first electrode layers and the plurality of second electrode layers are rectangular plates.

7. The capacitor of claim 1, further comprising a plurality of terminals disposed on one of the two of the plurality of first electrode layers disposed on outer surfaces of the capacitor.

8. The capacitor of claim 7, further comprising a plurality of terminals disposed on the other one of the two of the plurality of first electrode layers disposed on outer surfaces of the capacitor.

9. A printed circuit board comprising the capacitor of claim 1.

10. The printed circuit board of claim 9, wherein the capacitor is embedded in the printed circuit board.

11. An integrated-circuit package comprising the capacitor of claim 1.

12. A capacitor, comprising:
a plurality of first electrode layers including two of the plurality of first electrode layers disposed on outer surfaces of the capacitor;
a means for connecting outer edges of the plurality of first electrode layers;
a plurality of second electrode layers, the plurality of first electrode layers and the plurality of second electrode layers interleaved in alternating planes and separated by a dielectric; and
a means for connecting inner edges of the plurality of second electrode layers.

13. The capacitor of claim 12, wherein the means for connecting outer edges completely surrounds the plurality of first electrode layers.

14. The capacitor of claim 12, wherein the means for connecting inner edges is solid and passes though the plurality of first electrode layers.

15. The capacitor of claim 12, wherein the plurality of first electrode layers and the plurality of second electrode layers are discs.

16. The capacitor of claim 12, further comprising a plurality of terminals disposed on one of the two of the plurality of first electrode layers disposed on outer surfaces of the capacitor.

17. The capacitor of claim 16, further comprising a plurality of terminals disposed on the other one of the two of the plurality of first electrode layers disposed on outer surfaces of the capacitor.

18. A printed circuit board comprising the capacitor of claim 16.

19. The printed circuit board of claim 18, wherein the capacitor is embedded in the printed circuit board.

20. An integrated-circuit package comprising the capacitor of claim 16.
